(19) United States
(12) Patent Application Publication
(10) Pub. No.: US 2006/0040065 A1
(43) Pub. Date: Feb. 23, 2006

(54) Method for the surface activation on the metalization of electronic devices

(76) Inventors: Han-Chang Shih, Taipei City (TW); Jian-Hong Lin, Yunlin Hsien (TW); Wei-Jen Hsieh, Kaohsiung City (TW); Yi-Ying Tsai, Taoyuan Hsien (TW); Uei-Shin Chen, Taichung City (TW)

Correspondence Address: SUPREME PATENT SERVICES, P.O. BOX 2339, SARATOGA, CA, 95070-0339, US

(21) Appl. No.: 10/923,057

(22) Filed: Aug. 19, 2004

(51) Int. Cl. C23C 14/00; H01L 21/4763

(52) U.S. Cl. 427/523

(57) ABSTRACT

A method for surface activation on the metallization of electronic devices is provided. It uses plasma-immersion ion implantation and electroless plating to implant the seeds onto the diffusion barrier layer as catalyst for the electroless Cu plating to accomplish the ULSI interconnect metallization. It achieves electroless Cu plating in the deep 100 nm scaled line-width ULSI interconnect metallization by the Pd plasma implantation catalytic treatment. The method can fill the 100 nm line-width vias and trenches for gaining high quality electroless plated metal interconnects, and substitute for the traditional wet activation by SnCl₂ and PdCl₂ solution. For the plasma implanted seeds and electroless copper techniques, good Cu step coverage and gap-filling capability are observed in the trench and via metallization process with high adhesive strength. After thermal treatment, no obvious interfacial diffusion induced electric failure is found in the interface of the Cu/(implanted Pd)/TaN/FSG assembly. Good electric and interfacial structure reliability are observed in the process, too.

### FIELD OF THE INVENTION

The present invention generally relates to a method for surface activation on the metallization of electronic devices, and more specifically to a plasma ion implantation method to form an active layer on electronic devices.

### BACKGROUND OF THE INVENTION

The Damascene metallization technique, also called Damascene process, was proposed by IBM in 1983. The Damascene process differs from conventional metallization process in that the Damascene process first forms a pattern in the dielectric layer and then fills the gap (pattern) with metal, while the conventional aluminum process first forms a pattern using the metal before filling the dielectric layer. After the metallization, the Chemical Mechanic Polishing (CMP) method is used to flatten the surface and leave the metal in the trenches and vias. A multilevel interconnection device can be obtained by iterating the process for a few times. A diffusion barrier must be added between the copper and the dielectric layer to avoid the high-resistance compound formed by the diffusion of the two materials. The diffusion barrier layer is usually formed using an ionized metal plasma technology to cover the patterned dielectric layer with a Ta target. The conventional diffusion barrier layer, such as Ta, TaN, and TaSiN used in conventional semiconductor manufacture processes is not catalytic to the electroless copper plating manufacture processes, and thus an additional catalytic layer must be used to provide the growth of copper film.

The metal filling process requires a deposition technique with a good gap filling capacity in order to be used in the copper metal filling process for line width less than 100 nanometers. The interconnect manufactured with the conventional physical vapor phase deposition method is no longer suitable due to the problems caused by deep trench or high aspect ration via. In its place, the electroless or electroplating deposition technologies are gaining popularity because of the advantages of low manufacturing cost, low manufacturing temperature, high yield rate and the capability of forming alloy.

The current copper electroplating technique needs to deposit a continuous copper seed layer on the diffusion barrier layer. The discontinuity in the copper seed layer may cause the non-uniform distribution of the electroplating current and eventually lead to the formation of micro voids in the trench and the vias. The formation of micro voids not only increases the resistance of the interconnect, but also affects the device reliability. Compared to the current copper electroplating process, the seed layer of the electroless copper plating process only needs to be in a cluster form so that the growth of the copper film can be triggered when the catalyst is sufficient, without the external electrical current. Hence, the electroless copper plating process shows a better capacity in copper film growth selectivity, step-wise coverage and gap filling in the small line-width interconnection metallization process, compared to the copper electroplating process.

The electroless plating process was first discovered by Brenner and Riddell in their nickel electroplating experiments in 1946. In 1947, Narcus polished the first paper on electroless copper plating. The commercialization of the electroless copper plating started in via interconnect of the PCB in 1950s. The composition of the copper solution was difficult to control and prone to decomposition in the 1950s. The stability and the composition of the plating solution have both been greatly improved to meet the industrial requirement of filling the copper into the small-width trenches and vias in the last few decades. The simplicity, low-cost, and selective deposition are among the advantages of the manufacturing process.

There are two major parts of the electroless copper process. The first part includes the surface activation of the seed layer, and the second part includes the copper deposition in the plating solution. Most of the reported work, such as Shacham-Diamand and Dubin (Microelectronic Engineering 33, 47(1997)), focuses on the impact of the solution composition on the copper film, and the simulation of the chemical reaction mechanism. The seed layer is usually made by dipping in the PdCl₂ solution to form a Pd film for impregnating or sputtering catalyst atoms. Unfortunately, the seed layer of this type cannot provide sufficient adhesion as the deposition usually exists on the surface only. To improve the adhesion between the diffusion barrier and the electroless copper film, the plasma ion implantation has been proposed.

In U.S. Pat. No. 4,764,394 (1987), Conrad disclosed the plasma-immersion ion implantation (PIII) method. The method uses a large negative bias on the target and accelerates the ions around the target with the high voltage sheath so that the ions hit the target with a high speed to achieve the ion implantation. If a fixed bias is applied at the target, the thermal effect may cause the raise of the temperature of the target. In addition, if the target is non-metal, the implantation may cause the accumulation of the electric charge and may damage the target when overloaded. Therefore, instead of a fixed voltage, the negative bias uses the pulse. During the pulse, the ions are accelerated, while between the pulses, the ions diffuse freely to compensate the consumption of the ions in the sheath during the pressurized period. In this way, the implantation time can be extended and the energy-consumption can be reduced so that less heat is created to prevent from damaging the substrate.

Conventional ion implantation techniques use ion source to generate a beam of ions, which are accelerated by a bias of tens or hundreds of volts to hit the target. Because the cross section is far smaller than the size of the chip, a mechanical or electrostatic scanning must be used to achieve the uniformity of the injected dose. The complexity of the controlled structure increases the size and the cost of the system. On the other hand, the manufacturing cost is also increased due to the longer implantation time caused by the low implantation current. The plasma-immersion ion implantation method is developed to solve the aforementioned problems.

Plasma ion implantation has been widely developed in recent years due to the following advantages: (1) fast, (2) high uniformity, (3) good regeneration capacity, (4) precise control over the ion density of the implantation, (5) applicable to small-size and complicated-shape devices, (6) less restrictive on the purity of the ion source, (7) capable of implanting high density of ions in a thin area, (8) capable of multiple iterations of ion implantation to meet the implantation requirement, (9) a single ion implanter being able to implant different types of ions, (10) implanted ions capable of penetrating inert layer for ion doping, and (11) being able to use mask for implanting the required circuit.

Sputtering and cathodic arc are two types of the widely used metallic plasma sources. The cathodic arc can generate the plasma with a high density of 70%-90%, but has the disadvantage of generating macro particles during the process of forming plasma. To obtain a metallic plasma source with a high density and a high purity, a filter made of magnetic coil can be used to separate the metallic plasma and the metal micro particles. The sputtering system does not have the problem of micro particles, but suffers the low density of 10%-30%. If the electronic cyclic resonant or inductively coupled system is used to ionize the sputtered neutral metal atom, the density can be improved. Since only the ionized metal ions will be accelerated by the dragging of the negative bias, the high density and pure metallic plasma source is the key to the plasma ion implantation system.

### SUMMARY OF THE INVENTION

This invention has been made to achieve the advantages of utilizing the two types of metallic ion sources to ionize the Pd catalyst and the high pulse bias field of the base to construct plasma ion implantation systems. The primary object is to provide a method for surface activation on the metallization of electronic devices by combining the techniques of using plasma ion implantation and electroless plating to implant the seeds onto the diffusion barrier layer as catalyst for the electroless Cu plating to accomplish the ULSI interconnect metallization.

According to the invention, the method mainly comprises the following steps: (a) generating a catalyst metal plasma having a high density and a high purity, (b) using a plasma ion implantation to implant the surface of an electronic device with the catalyst metal plasma, (c) applying a negative pulsed bias to the electronic device, and (d) applying an electroless plating process for metallization to form metal interconnect.

In the invention, a plasma ion implantation system using an ionized metal sputtering plasma and a plasma-immersion ion implantation system using a filtered cathodic arc plasma are respectively utilized in order to generate the catalyst metal plasma having a high density and a high purity.

Accordingly, electroless Cu plating in the deep 100 nm scaled line-width ULSI interconnect metallization has been successfully achieved by the Pd plasma implantation catalytic treatment. This results in an extraordinary ability for filling the 100 nm line-width vias and trenches for gaining high quality electroless plated Cu interconnect, and thus qualifies to substitute for the traditional wet activation by SnCl₂ and PdCl₂ solution. For the plasma implanted seeds and electroless copper techniques, good Cu step coverage and gap-filling capability are observed in the trench and via metallization process with high adhesive strength. After thermal treatment, no obvious interfacial diffusion induced electric failure is found in the interface of the Cu/(implanted Pd)/TaN/FSG assembly. Good electric and interfacial structure reliability are observed in the process, too.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 shows a schematic view of a plasma-immersion ion implantation system using an ionized metal sputtering plasma.

FIG. 2 shows a schematic view of a plasma-immersion ion implantation system using a filtered cathodic arc plasma.

FIGS. 3A-3C show a schematic view of the metallization process of the copper interconnect.

FIG. 4 shows the relation between the energy of plasma-immersion ion implantation Pd and the adhesion strength of the copper film on TaN.

FIG. 5 shows the XRD verification of the annealing temperature effect on the structure of the assembly Cu/(Implanted Pd)/TaN/Si layer.

FIG. 6 shows the annealing temperature effect on the copper film resistance coefficient.

FIG. 7 shows the steps for surface activation on the metallization of electronic devices according to the present invention.

### DETAILED DESCRIPTION OF THE PREFERRED EMBODIMENTS

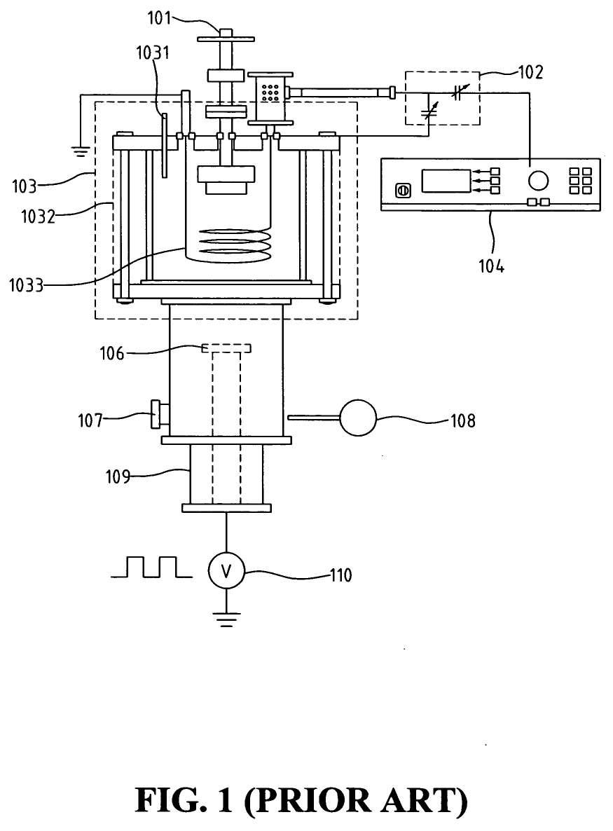

FIG. 1 shows a schematic view of a plasma-immersion ion implantation system using an ionized sputter. Referring to FIG. 1, the plasma-immersion ion implantation system includes a sputtering gun 101, a matching box 102, a vacuum chamber 103 coupled with sputtering gun 101, further including a gas-in vent 1031, a RF shielding unit 1032 and a magnetic coil 1033 coupled with matching box 102, a RF power supply 104 coupled with matching box 102 to provide RF power to magnetic coil 1033, a wafer holder 106 for holding the wafer, a pumping 107, a vacuum gauge 108, a high voltage stage 109, and a negative pulsed bias 110 connected to high voltage stage 109. The Pd ions are sputtered from sputtering gun 101 at the top of vacuum chamber 103 and passing through magnetic coil 1033. Because the initial sputtered Pd plasma has a low ion density, the Pd atoms are ionized when passing through magnetic coil 1033. The ionized atoms are dragged by high voltage stage 109 connected to negative pulsed bias 110 to hit the wafer at wafer holder 106 to generate a large area of ion implantation.

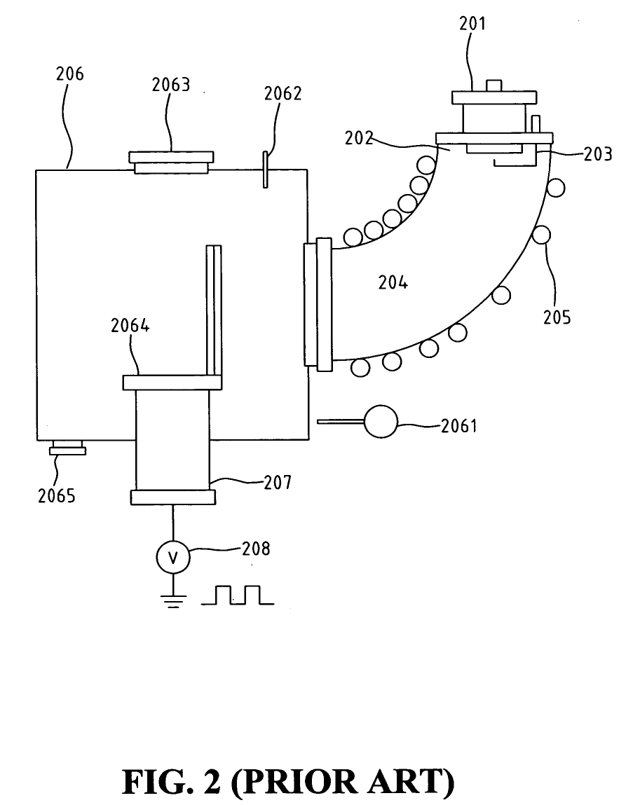

FIG. 2 shows a schematic view of a plasma-immersion ion implantation system using filtered cathodic arc plasma. Referring to FIG. 2, the plasma-immersion ion implantation system includes a DC power 201, a target 202, a trigger 203, a filter 204, a magnetic coils 205 surrounding filter 204, a vacuum chamber 206, further including a vacuum gauge 2061, a gas-in vent 2062, a window 2063, a wafer holder 2064, a pumping 2065, a high voltage stage 207, and a negative pulsed bias 208. A large amount of Pd ions and a small amount of Pd macro particles are discharged by the arc to in front of target 202. As shown in FIG. 2, bended filter 204 surrounded by magnetic coil 205 provides the magnetic field to attract the ions into vacuum chamber 206. Because the neutral particles are not attracted by the magnetic field, only the pure and high density plasma will be attracted into vacuum chamber 206. The Pd ions are later dragged by high voltage stage 207 connected to negative pulsed bias 208 to hit the wafer at wafer holder 2064 to generate a large area of ion implantation.

With the ionized metal sputtering plasma system and the filtered cathodic arc plasma system, the invention generates a catalyst metal plasma having a high density and a high purity. With the catalyst metal plasma, this invention uses a plasma ion implantation to implant the surface of an electronic device, such as a wafer. Accordingly, the ionized metal sputtering plasma system ionizes the catalyst atoms by using an inductively coupled plasma (ICP) technique. While the filtered cathodic arc plasma system purifies the catalyst metal plasma. The catalyst metal plasma may include Pd, Cu, Pt, and the metal that can be made as a catalyst.

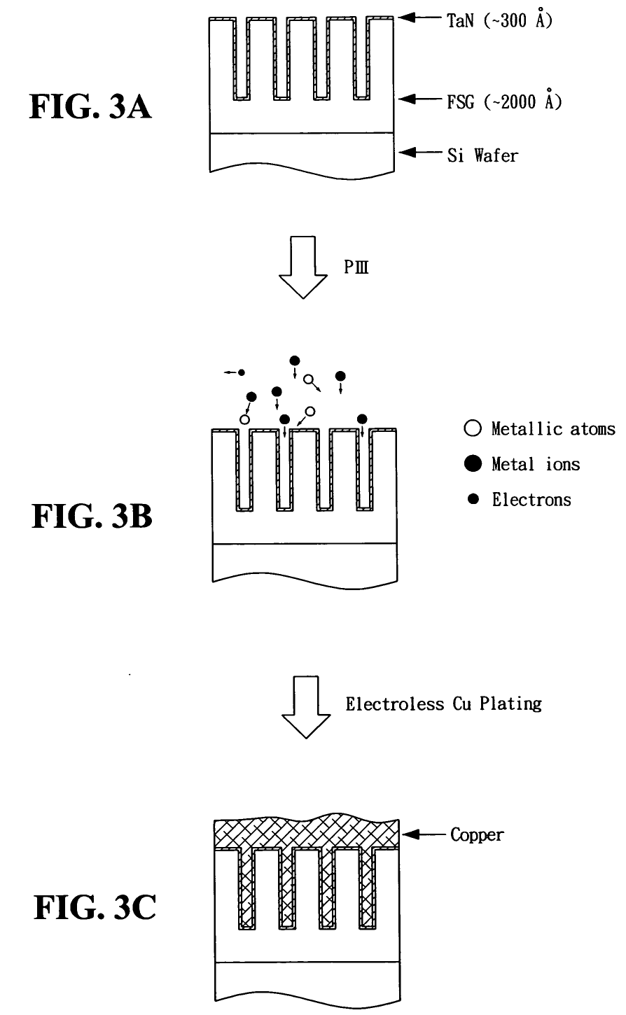

FIGS. 3A-3C show the metallization process of metal interconnects. Initially, FIG. 3A shows the cross-sectional view of a wafer, including a diffusion barrier layer (i.e. TaN layer) being on top of an FSG layer, which is on top of the Si wafer. Trenches and vias are formed in the TaN layer. FIG. 3B shows that metallic atoms, metal ions and electrons are implanted in the plasma-immersion ion implantation system. Once the Pd implantation is done and a catalyst layer is grown and available, the wafer is placed into an electroless plating system to grow a metal film, as shown in FIG. 3C. According to the invention, the Pd parameter is adjustable in the plasma-immersion ion implantation system so that a better trench and via filling capability can be obtained in the electroless plating system.

As mentioned before, the present invention combines the techniques of using plasma-immersion ion implantation and electroless plating to implant the seeds onto the diffusion barrier layer as catalyst for the electroless Cu plating to accomplish the ULSI interconnect metallization. In the ionized metal sputtering plasma system, preferred conditions for the implantation catalytic treatment are as follows. The bias voltage for Pd ions is −30V of DC. The Pd working pressure of plasma-immersion ion implantation is Ar 10 mtorr. The Pd implantation dose is 5×10¹⁴ cm⁻². The substrate bias voltage is −4 kV with 1 μs duration and 200 Hz frequency. The ICP input power is set at 120 W with a feedback power less than 1 W. In the filtered cathodic arc plasma system, preferred conditions for the implantation catalytic treatment are as follows. The bias voltage for Pd ions is 60 A/150V of DC. The Pd working pressure of plasma-immersion ion implantation is Ar 0.5 mtorr. The Pd implantation dose is 5×10¹⁴ cm⁻². The substrate bias voltage is −4 kV with 5 μs duration and 50 kHz frequency. The filter spiral pipe current is set at 3 A (votage is in the range of 20-30 V).

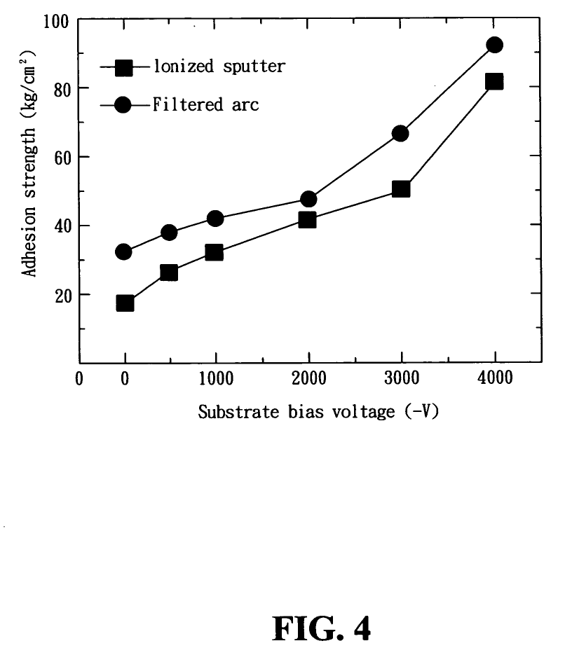

FIG. 4 shows relation between the adhesive strength and the substrate bias voltage. As shown in FIG. 4, the adhesive strength between the electroless plating copper and the wafer is about 20 kg/cm² under no substrate bias voltage. While the adhesive strength is approximate to 90 kg/cm² under −4 kV substrate bias voltage. In both plasma-immersion ion implantation systems of using the ionized metal sputtering plasma and the filtered cathodic arc plasma, the adhesive strength between the electroless plating copper and the wafer increases as the substrate bias voltage increases. In other words, the substrate bias voltage can improve the adhesive strength between the electroless plating copper and the wafer. In addition, if a thermal treatment at 300° C. is applied for an hour, the adhesive strength also increases. This is because the copper and the TaN bounds stronger after the thermal treatment.

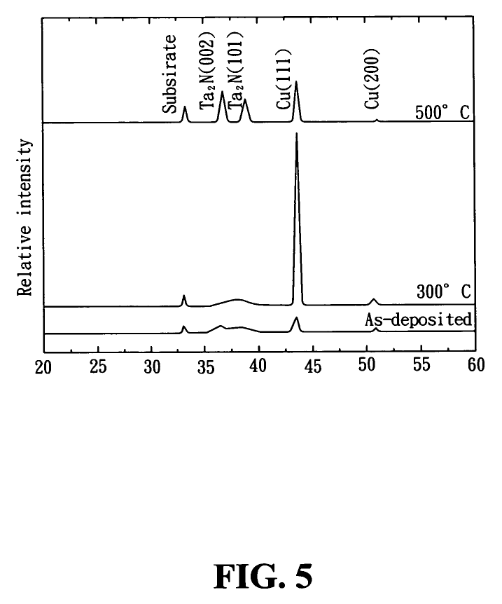

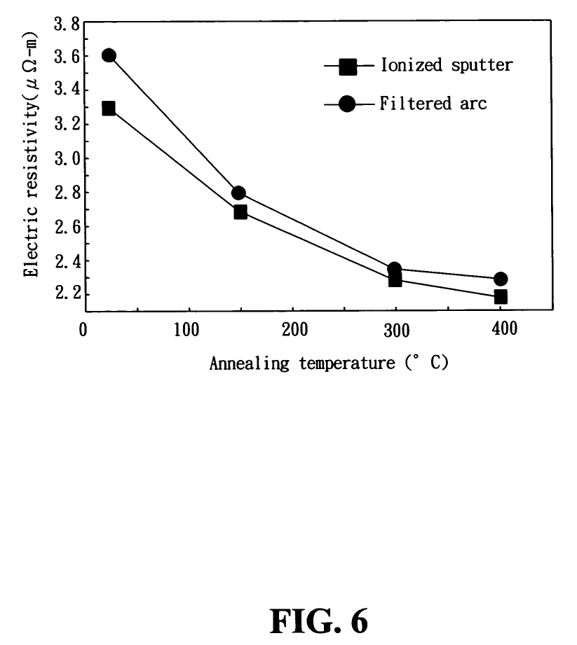

FIG. 5 shows the reliability of the interface between copper and TaN. The wafer does not show sign of copper-silicon compound after the thermal treatment. This shows that the diffusion barrier layer TaN is not damaged during the Pd plasma-immersion ion implantation process. The electric resistivity distribution is shown in FIG. 6. As shown in FIG. 6, the electric resistivity of the copper film (about 0.2 μm thickness) is reduced to below 2.2 μΩ-cm, which is close to the copper bulk theoretic electric resistivity 1.67 μΩ-cm, after the thermal treatment at 300° C. for an hour.

With the plasma-immersion ion implantation using ionized metal sputtering plasma for plasma doping Pd, an experiment uses ICP input power set at 120 W and maintains the negative bias voltage at −500V. The experiment shows that the result of the electroless copper plating can exhibit good copper film step coverage capability. While keeping the ICP input power of 120 W and increasing the negative bias voltage up to −4 KV, large amount of ionized Pd atoms enters the trench and the via following the bias electrical field. After the electrcoless copper plating, the growth mechanism of copper film becomes the bottom-up filling mechanism, and no cracks or residual holes are left unfilled. In the experiment, it has been observed that the width of via is 250 nm and the depth-width ratio of via is about 6.5. The trench has a width 300 nm and a depth-width ratio about 2.5. A preferred range for negative bias voltage to allow the ionized Pd atoms entering the trench is between −500V and −15 kV.

With the plasma-immersion ion implantation using filtered cathodic arc plasma, a growth mechanism similar to that of the ionized metal sputtering plasma can be obtained. An experiment shows the copper growth in the via having a width 300 nm and the depth-width ratio is about 5. Similarly, the metal interconnect is fully filled, and the filling can improve the reliability against both electromigration and the stress migration.

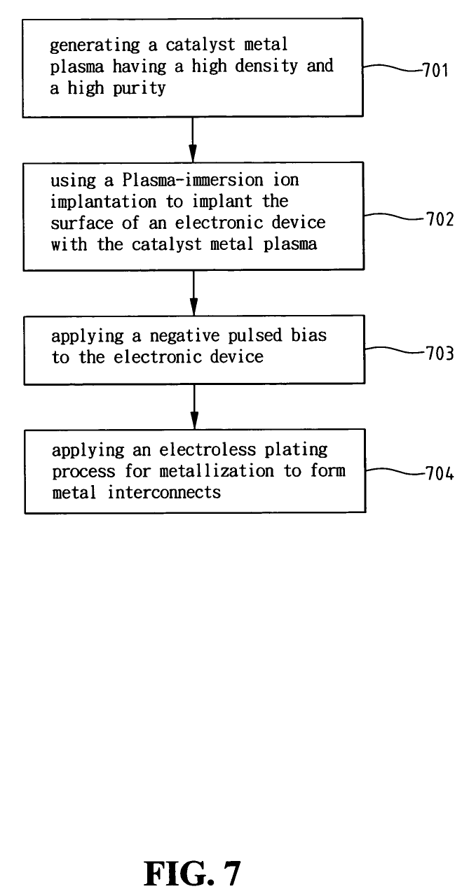

In summary, the present invention provides a method for surface activation on the metallization of electronic devices. As shown in FIG. 7, it mainly comprises the steps of (a) generating a catalyst metal plasma having a high density and a high purity, i.e. step 701, (b) using a plasma-immersion ion implantation to implant the surface of an electronic device with the catalyst metal plasma, i.e. step 702, (c) applying a negative pulsed bias to the electronic device, i.e. step 703, and (d) applying an electroless plating process for metallization to form metal interconnects, i.e. step 704.

As mentioned earlier, the conventional electroless copper plating process relies on the wet activation and sensitization process, which is not applicable when the device for plating has an inert surface. On the other hand, when the conventional sputtering is used in manufacturing activation layer, the low density of the plasma cannot implant the catalyst into the surface of a device having a complicated shape. This leads to the problem of discontinuity of coverage in the electroless copper plating. The present invention can replace the wet activation and sensitization process used by the conventional electroless copper plating. The catalyst layer generated by the present invention has a high purity and can selectively activate a large area for plating. By improving the Pd and the TaN mechanical interface, the adhesive strength between the copper film and the TaN is improved. The subsequent thermal treatment shows that the implanting process does not affect the reliability between the copper film and the TaN. The present invention overcomes the aforementioned problems in the conventional technique to obtain a high reliability of the device.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method for surface activation on the metallization of electronic devices comprising the steps of:
(a) generating a catalyst metal plasma having a high density and a high purity;
(b) using a plasma-immersion ion implantation to implant the surface of an electronic device with said catalyst metal plasma;
(c) applying a negative pulsed bias to said electronic device; and
(d) applying an electroless plating process for metallization to form metal interconnects.

2. The method as claimed in claim 1, wherein said catalyst metal plasma in said step (a) is ionized by an inductively coupled plasma technique.

3. The method as claimed in claim 1, wherein said catalyst metal plasma in said step (a) is purified by a filtered cathodic arc system.

4. The method as claimed in claim 1, wherein said negative pulsed bias in said step (c) is in the range of −500V to −15 kV.

5. The method as claimed in claim 1, wherein said catalyst metal plasma includes Pd, Cu, Pt, and the metal that is made as a catalyst.

6. The method as claimed in claim 1, wherein a thermal treatment step is applied after said step (d).

7. The method as claimed in claim 1, wherein said step (d) further comprises the steps of:
(d1) placing said electronic device in a plasma-immersion ion implantation system for plasma-immersion ion implantation; and
(d2) placing said electronic device into an electroless plating system to grow a metal film, once said plasma-immersion ion implantation is done and a catalyst layer is grown and available.

8. The method as claimed in claim 7, wherein a step of adjusting implantation parameter is applied after said step (d2) to achieve a better trench and via filling capability in said electroless plating process.

9. The method as claimed in claim 8, wherein said step of adjusting implantation parameter is to adjust the implantation parameter of said catalyst metal plasma.
